(19) United States
(12) Patent Application Publication
(10) Pub. No.: US 2015/0115956 A1
(43) Pub. Date: Apr. 30, 2015

(54) SYSTEM AND METHOD FOR QUIET MAGNETIC RESONANCE IMAGING

(71) Applicants: Jerome L. Ackerman, Newton, MA (US); Kenneth Kwong, Boston, MA (US); Timothy G. Reese, Medford, MA (US); Yaotang WU, Belmont, MA (US)

(72) Inventors: Jerome L. Ackerman, Newton, MA (US); Kenneth Kwong, Boston, MA (US); Timothy G. Reese, Medford, MA (US); Yaotang WU, Belmont, MA (US)

(21) Appl. No.: 14/396,541

(22) PCT Filed: Mar. 13, 2013
(86) PCT No.: PCT/US2013/030828

§ 371 Date: Oct. 23, 2014

Related U.S. Application Data
(60) Provisional application No. 61/640,304, filed on Apr. 30, 2012.

(51) Int. Cl. G01R 33/42; G01R 33/44

(52) U.S. Cl. CPC G01R 33/42; G01R 33/44
USPC 324/309; 324/322

(57) ABSTRACT

A system and method for performing quiet magnetic resonance imaging (“MRI”) are provided. An MRI system is directed to perform a pulse sequence that includes a magnetic field gradient s tapped through a plurality of different gradient component amplitude values in a manner that controls the difference between successive gradient amplitudes. In this way, force changes generated during the transition from one gradient component amplitude to the next are controlled, thereby resulting in a significant noise reduction. Additionally, the gradient amplitude values are ordered such that the transition of the gradient component amplitude in successive repetitions of the pulse sequence is controlled, thereby mitigating the generation of forces between pulse sequence repetitions.

### CROSS-REFERENCE

This application is based on, claims the benefit of, and incorporates herein by reference U.S. Provisional Application Ser. No. 61/640,304, filed Apr. 30, 2012, and entitled “SYSTEM AND METHOD FOR QUIET MAGNETIC RESONANCE IMAGING.”

### BACKGROUND OF THE INVENTION

The field of the invention is systems and methods for magnetic resonance imaging (“MRI”). More particularly, the invention relates to systems and methods for substantially reducing the acoustic noise generated by an MRI system.

Magnetic resonance imaging (“MRI”) uses the nuclear magnetic resonance (“NMR”) phenomenon to produce images. When an object or a substance, for example human tissue or a human body part, is subjected to a uniform magnetic field (polarizing field B₀), the individual magnetic moments of the nuclei (“spins”) in the tissue tend to align with this polarizing field, leading to a net macroscopic magnetization (the vector sum of the individual magnetic moments) that aligns parallel to the polarizing field. The transverse vector components of the individual moments, and any macroscopic transverse component, precess about the polarizing field at the Larmor frequency characteristic of the nuclear isotope and proportional to the strength of the polarizing field. If the substance, or tissue, is subjected to an oscillating magnetic field (excitation field B₁) that is in the x-y plane (perpendicular to the direction of the polarizing field) and that is near the Larmor frequency, the net aligned moment, M_{z}, may be rotated, or “tipped,” into the x-y plane to produce a net transverse magnetic moment M_{xy} which precesses about the polarizing field at the Larmor frequency. This precessing magnetic moment may be detected through the radiofrequency (“RF”) voltage it induces in a nearby inductor (RF coil) after the excitation signal B₁ is terminated, and this voltage signal may be amplified, digitized and processed to form a spectrum of the substance or an image of the body part.

When utilizing these “MR” signals to produce images, pulsed magnetic field gradients (Gₓ, G_{y}, and G_{z}) are added to the polarizing field. Typically, the region to be imaged is scanned by a sequence of measurement cycles (pulse sequences) in which these gradient pulses vary according to the particular localization method being used. The resulting set of received MR signals are digitized and processed to reconstruct the image using one of many well known reconstruction techniques.

MRI scanning is often accompanied by intense acoustic noise resulting from mechanical forces between the main magnetic field and the magnetic gradient coils when driven by pulsed electrical currents. These mechanical forces originate in the Lorentz force between the main magnet and the gradient coil structure when it carries the large currents which generate the gradient fields. Because pulsed gradients are normally employed in typical pulse sequences, the forces are pulsed as well. The larger or more rapid the gradient transition (the ramp up or ramp down rate of the gradient pulse), the more intense the force change and, therefore, the acoustic emission. All conventional MRI pulse sequences include substantial gradient transitions and are, therefore, noisy.

Because of the intense acoustic noise produced during an MRI scan, patients are often required to wear hearing protection. Even with hearing protection, the high acoustic levels can be highly uncomfortable and intimidating to patients, especially children, psychiatric patients, and anxious individuals. In addition, high acoustic levels can degrade images by inducing vibratory motion of tissues (causing image blurring), or by inducing motion of metallic structures of the scanner or metal implants in the body (generating spurious oscillatory magnetic fields or modulating the tuning of RF coils). These high acoustic levels may also lead to scanner failure resulting directly from the intense vibration and fatigue of metal (especially copper wires), and abrasion of electrical insulators, as well as indirectly from the pulsed currents in conductors which are immersed in the magnetic field. Finally, the pulsed gradient fields induce eddy currents in the metallic structures of the scanner, which in turn create spurious magnetic field gradients that interfere with the scanning process.

Another consequence of large and rapid gradient transitions in the pulse sequence is the possibility of peripheral nerve stimulation, where rapidly changing magnetic fluxes induce electric potentials in electrical conductors, including nerves. Peripheral nerve stimulation can lead to involuntary, sometimes painful, muscle contractions and sensations. The same propensity of the switched gradient fields to generate electromotive forces can result in heating and damage to implanted conductive structures and electronic circuits and the surrounding tissue, as well as heating of metallic parts of RF coils (which could in turn burn subjects' skin).

The most extreme noise is created by high speed echo-planar imaging (“EPI”) pulse sequences, which are very frequently used in functional MRI (“fMRI”) applications. And yet, these are precisely the applications in which a quiet scanning procedure would be the most advantageous. Auditory, sleep, and resting-state fMRI studies may be compromised by scanner noise. In addition, fMRI studies may also be compromised because a patient's mental concentration can be inhibited in the noisy environment of the MRI system.

There have been numerous attempts at reducing acoustic noise during an MRI scan. These attempts can be classified into the following general approaches. In one approach, the patient is provided with a hearing protection device, such as earplugs or headphones or both. Generally, hearing protection results in only about a 10-15 dB reduction in sound pressure level at most. Sound deadening insulation, including vacuum insulation, may be placed in the magnet to augment the sound pressure reduction. In another approach, the gradient coil is made very stiff and massive, to minimize its movement and acoustic emission. Alternatively, gradient coils with force-balanced and torque-balanced windings and damped mechanical resonances are designed to reduce gradient coil motion and acoustic emission. In still another hardware-based approach, unusual mechanical interventions, such as mechanically rotated electrically static gradients, may be used. Force-balanced and torque-balanced gradients, and other mechanical approaches, have not found widespread application.

In yet another approach, shaped gradient pulses with lower transition rates and reduced spectral power at the most objectionable frequencies are used. Of the attempted methods, the best reported reduction in sound pressure level was achieved with alterations in the gradient pulse profiles, such as by substituting sinusoidal pulses for trapezoidal pulses. In a few cases, noise reductions on the order of 30 dB have been reported. Scanner manufacturers may impose software restrictions on pulse sequences to exclude programming gradient pulse rates and directions that tend to set up particularly intense or damaging vibrations of the gradient system, or to warn the operator of such situations before the scan starts.

Other approaches have included using active acoustic feedback to cancel scanner noise and, for fMRI, designing functional task paradigms to be timed such that the cognitive tasks coincide with less noisy intervals. Unfortunately, all of these attempts to control the acoustic noise associated with MRI have substantial drawbacks or limitations.

It would therefore be desirable to provide a system and method for performing magnetic resonance imaging with a substantial noise reduction over conventional MRI systems.

### SUMMARY OF THE INVENTION

The present invention overcomes the aforementioned drawbacks by providing a system and method for magnetic resonance imaging in which scanner noise is substantially reduced by continuously establishing a magnetic field gradient during a pulse sequence and by controlling the difference in subsequent gradient amplitude steps in the vector components of the magnetic field gradient.

It is an aspect of the invention to provide a method for controlling a magnetic resonance imaging (MRI) system to control auditory noise. The method includes directing an MRI system to perform a pulse sequence that includes maintaining a magnetic field gradient during each repetition of the pulse sequence and stepping the magnetic field gradient vector components through a plurality of different gradient amplitudes in a pattern that controls a difference between successive gradient amplitudes to be less than a threshold to control auditory noise caused by force changes generated during transitions between the successive gradient amplitudes. The method also includes applying the pattern to control a transition between successive gradient amplitudes in successive repetitions of the pulse sequence to be less than the threshold to control auditory noise caused by force changes generated during transitions between the successive gradient amplitudes between the successive repetitions of the pulse sequence.

It is another aspect of the invention to provide a magnetic resonance imaging (MRI) system that includes a magnet system configured to generate a polarizing magnetic field about at least a portion of a subject arranged in the MRI system, a magnetic gradient system including a plurality of magnetic gradient coils configured to apply at least one magnetic gradient field to the polarizing magnetic field, and a radio frequency (RF) system configured to apply an RF field to the subject and to receive magnetic resonance signals therefrom. The MRI system also includes a computer system programmed to direct the magnetic gradient system to step the magnetic field gradient vector components through a plurality of gradient amplitude values in which a difference between successive gradient amplitude values is less than a threshold designed to control force changes generated between the magnet system and the magnetic gradient system. The computer is also programmed to direct the magnetic gradient system to order the plurality of magnetic gradient amplitude values according to a pattern to control a transition between successive repetitions of a pulse sequence to avoid gaps in the magnetic field gradient and maintain the difference between successive gradient amplitude values to be less than the threshold. The computer is further programmed to direct the RF system to coordinate with the magnetic gradient system to acquire MR imaging data from the subject and reconstruct an image of the subject from the MR imaging data.

It is yet another aspect of the invention to provide a method for magnetic resonance imaging (MRI) with significant noise reduction. The method includes directing an MRI system to perform a pulse sequence that includes continuously establishing a magnetic field gradient during each repetition of the pulse sequence and stepping the continuously established magnetic field gradient vector components through a plurality of different gradient amplitudes such that a difference between successive gradient amplitudes is sufficiently small so as to substantially mitigate force changes generated during transitions between the successive gradient amplitudes. The plurality of different gradient amplitudes are ordered such that a transition of the gradient amplitude in successive repetitions of the pulse sequence is sufficiently small so as to substantially mitigate force changes generated during transitions between the successive repetitions of the pulse sequence.

It is still another aspect of the invention to provide a magnetic resonance imaging (MRI) system that includes a magnet system configured to generate a polarizing magnetic field about at least a portion of a subject arranged in the MRI system, a magnetic gradient system including a plurality of magnetic gradient coils configured to apply at least one magnetic gradient field to the polarizing magnetic field, and a radio frequency (RF) system configured to apply an RF field to the subject and to receive magnetic resonance signals therefrom. The MRI system also includes a computer system programmed to direct the magnetic gradient system to continuously establish a magnetic field gradient and direct the magnetic gradient system to step the continuously established magnetic field gradient vector components through a plurality of gradient amplitude values in which a difference between each successive gradient amplitude value is sufficiently small so as to substantially mitigate force changes being generated between the magnet system and the magnetic gradient system. The computer is further programmed to direct the magnetic gradient system to order the plurality of magnetic gradient amplitude values such that a transition between successive repetitions of a pulse sequence that includes the continuously established magnetic field gradient is sufficiently small so as to substantially mitigate force changes being generated between the magnet system and the magnetic gradient system.

The foregoing and other aspects and advantages of the invention will appear from the following description. In the description, reference is made to the accompanying drawings which form a part hereof, and in which there is shown by way of illustration a preferred embodiment of the invention. Such embodiment does not necessarily represent the full scope of the invention, however, and reference is made therefore to the claims and herein for interpreting the scope of the invention.

### BRIEF DESCRIPTION OF THE DRAWINGS

FIG. 1 is a block diagram of an example of an MRI system configured in accordance with the present invention.

FIG. 2 is an example of a pulse sequence that is substantially quiet when performed by an MRI system, such as illustrated in FIG. 1.

FIG. 3 is an example of a spatial-encoding gradient pattern that may be used in connection with the pulse sequence of FIG. 1.

FIG. 4 is an example of an Archimedean spiral k-space trajectory that may be traversed with the spatial-encoding gradients of FIG. 2.

FIG. 5 is a flow chart setting forth the steps of an example of a method in accordance with the present invention.

### DETAILED DESCRIPTION OF THE INVENTION

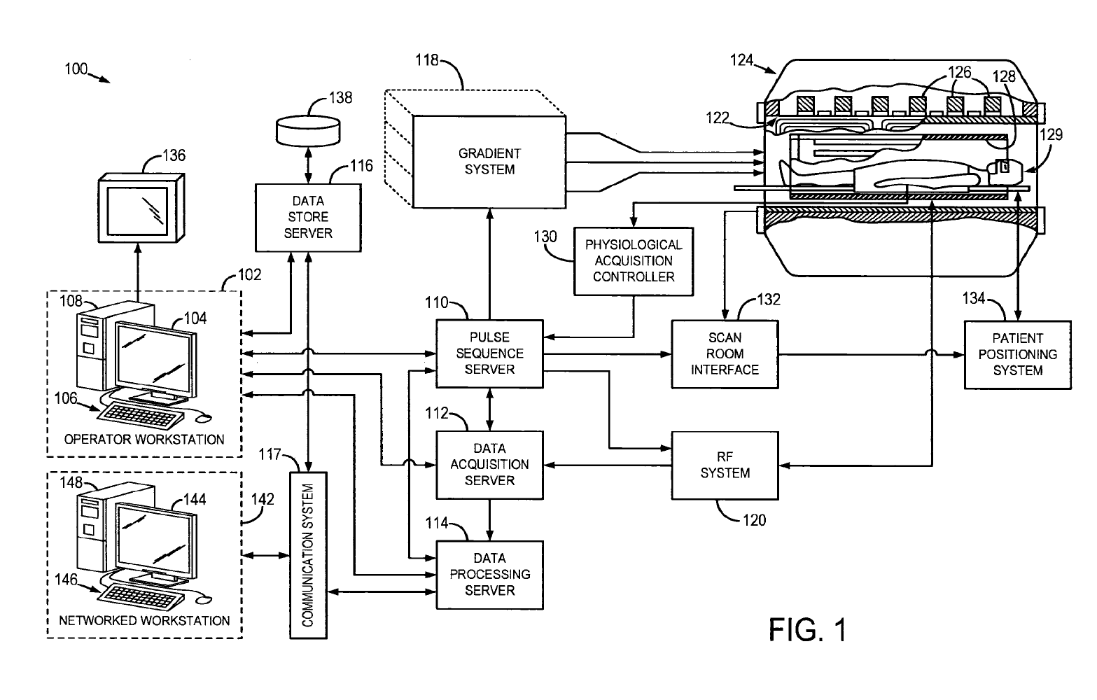

Referring particularly now to FIG. 1, an example of a MRI system 100 is illustrated. The MRI system 100 includes an operator workstation 102, which will typically include a display 104, one or more input devices 106, such as a keyboard and mouse, and a processor 108. The processor 108 may include a commercially available programmable machine running a commercially available operating system. The operator workstation 102 provides the operator interface that enables scan prescriptions to be entered into the MRI system 100. In general, the operator workstation 102 may be coupled to four servers: a pulse sequence server 110; a data acquisition server 112; a data processing server 114; and a data store server 116. The operator workstation 102 and each server 110, 112, 114, and 116 are connected to communicate with each other. For example, the servers 110, 112, 114, and 116 may be connected via a communication system 117, which may include any suitable network connection, whether wired, wireless, or a combination of both. As an example, the communication system 117 may include both proprietary or dedicated networks, as well as open networks, such as the internet.

The pulse sequence server 110 functions in response to instructions downloaded from the operator workstation 102 to operate a gradient system 118 and an RF system 120. Gradient waveforms necessary to perform the prescribed scan are produced and applied to the gradient system 118, which excites gradient coils in an assembly 122 to produce the magnetic field gradients Gₓ, G_{y}, and G_{z} used for position encoding magnetic resonance signals. The gradient coil assembly 122 forms part of a magnet assembly 124 that includes a polarizing magnet 126 and a whole-body RF coil 128 and/or local coil, such as a head coil 129.

RF waveforms are applied by the RF system 120 to the RF coil 128, or a separate local coil, such as the head coil 129, in order to perform the prescribed magnetic resonance pulse sequence. Responsive magnetic resonance signals detected by the RF coil 128, or a separate local coil, such as the head coil 129, are received by the RF system 120, where they are amplified, demodulated, filtered, and digitized under direction of commands produced by the pulse sequence server 110. The RF system 120 includes an RF transmitter for producing a wide variety of RF pulses used in MRI pulse sequences. The RF transmitter is responsive to the scan prescription and direction from the pulse sequence server 110 to produce RF pulses of the desired frequency, phase, and pulse amplitude waveform. The generated RF pulses may be applied to the whole-body RF coil 128 or to one or more local coils or coil arrays, such as the head coil 129.

The RF system 120 also includes one or more RF receiver channels. Each RF receiver channel includes an RF preamplifier that amplifies the magnetic resonance signal received by the coil 128/129 to which it is connected, and a detector that detects and digitizes the I and Q quadrature components of the received magnetic resonance signal. The magnitude of the received magnetic resonance signal may, therefore, be determined at any sampled point by the square root of the sum of the squares of the I and Q components:

M=\sqrt{I²+Q²} (1):

and the phase of the received magnetic resonance signal may also be determined according to the following relationship:

$$ϕ = {tan}^{- 1} ( \frac{Q}{I} ) . \qquad ( 2 )$$

The pulse sequence server 110 also optionally receives patient data from a physiological acquisition controller 130. By way of example, the physiological acquisition controller 130 may receive signals from a number of different sensors connected to the patient, such as electrocardiograph (“ECG”) signals from electrodes, or respiratory signals from a respiratory bellows or other respiratory monitoring device. Such signals are typically used by the pulse sequence server 110 to synchronize, or “gate,” the performance of the scan with the subject's heart beat or respiration.

The pulse sequence server 110 also connects to a scan room interface circuit 132 that receives signals from various sensors associated with the condition of the patient and the magnet system. It is also through the scan room interface circuit 132 that a patient positioning system 134 receives commands to move the patient to desired positions during the scan.

The digitized magnetic resonance signal samples produced by the RF system 120 are received by the data acquisition server 112. The data acquisition server 112 operates in response to instructions downloaded from the operator workstation 102 to receive the real-time magnetic resonance data and provide buffer storage, such that no data is lost by data overrun. In some scans, the data acquisition server 112 does little more than pass the acquired magnetic resonance data to the data processor server 114. However, in scans that require information derived from acquired magnetic resonance data to control the further performance of the scan, the data acquisition server 112 is programmed to produce such information and convey it to the pulse sequence server 110. For example, during prescans, magnetic resonance data is acquired and used to calibrate the pulse sequence performed by the pulse sequence server 110. As another example, navigator signals may be acquired and used to adjust the operating parameters of the RF system 120 or the gradient system 118, or to control the view order in which k-space is sampled. In still another example, the data acquisition server 112 may also be employed to process magnetic resonance signals used to detect the arrival of a contrast agent in a magnetic resonance angiography (MRA) scan. By way of example, the data acquisition server 112 acquires magnetic resonance data and processes it in real-time to produce information that is used to control the scan.

The data processing server 114 receives magnetic resonance data from the data acquisition server 112 and processes it in accordance with instructions downloaded from the operator workstation 102. Such processing may, for example, include one or more of the following: reconstructing two-dimensional or three-dimensional images by performing a Fourier transformation of raw k-space data; performing other image reconstruction algorithms, such as iterative or backprojection reconstruction algorithms; applying filters to raw k-space data or to reconstructed images; generating functional magnetic resonance images; calculating motion or flow images; and so on.

It is contemplated that reconstruction may be performed using a variety of reconstruction techniques. For example, two such reconstruction methods, particularly when applied to projection imaging acquisitions, are described in U.S. Pat. No. 5,079,697, entitled “Distortion Reduction in Projection Imaging by Manipulation of Fourier Transform of Projection Sample” by Chesler, and U.S. Pat. No. 6,879,156, entitled “Reducing dead-time effect in MRI projection” also by Chesler. The latter methods, for example, can be modified to accept gradient orderings described above and reconstruct the acquired data into an image. In the case of 3D radial FID MRI of short T₂ substances, the methods of U.S. Pat. No. 6,185,444, entitled “Solid-state magnetic resonance imaging” by Ackerman et al. and U.S. Pat. No. 7,574,248, entitled “Method and apparatus for quantitative bone matrix imaging by magnetic resonance imaging” also by Ackerman et al., are particularly useful. U.S. Pat. Nos. 5,079,697; 6,879,156; 6,185,444; and 7,574,248 are hereby incorporated by reference in their entirety.

Images reconstructed by the data processing server 114 are conveyed back to the operator workstation 102 where they are stored. Real-time images are stored in a data base memory cache (not shown in FIG. 1), from which they may be output to operator display 104 or a display 136 that is located near the magnet assembly 124 for use by attending physicians. Batch mode images or selected real time images are stored in a host database on disc storage 138. When such images have been reconstructed and transferred to storage, the data processing server 114 notifies the data store server 116 on the operator workstation 102. The operator workstation 102 may be used by an operator to archive the images, produce films, or send the images via a network to other facilities.

The MRI system 100 may also include one or more networked workstations 142. By way of example, a networked workstation 142 may include a display 144; one or more input devices 146, such as a keyboard and mouse; and a processor 148. The networked workstation 142 may be located within the same facility as the operator workstation 102, or in a different facility, such as a different healthcare institution or clinic.

The networked workstation 142, whether within the same facility or in a different facility as the operator workstation 102, may gain remote access to the data processing server 114 or data store server 116 via the communication system 117. Accordingly, multiple networked workstations 142 may have access to the data processing server 114 and the data store server 116. In this manner, magnetic resonance data, reconstructed images, or other data may exchanged between the data processing server 114 or the data store server 116 and the networked workstations 142, such that the data or images may be remotely processed by a networked workstation 142. This data may be exchanged in any suitable format, such as in accordance with the transmission control protocol (TCP), the internet protocol (IP), or other known or suitable protocols.

A system and method for very quiet or substantially silent MRI scanning, for example, using an MRI system such as described with respect to FIG. 1, is provided. Hereinafter, very quiet or comparatively or substantially silent MRI methods will be referred to as “quiet.” As an example, very quiet or substantially silent MRI scanning may include auditory noise generated by operation of the gradient system of the MRI system of, for example, 50 dB sound pressure level.

This system and method can improve imaging applications, such as functional MR for auditory, sleep, and resting-state studies; angiography; abdominal MRI; and others. Quiet MRI offers important advantages, including improved safety and patient experience. With a substantial reduction in MRI scanner noise, subjects participating in an fMRI study can truly focus on the tasks at hand, and subjects in general can enjoy music or video during an imaging scan. In addition, MRI system engineering can be simplified by implementing the present invention because of the reduced mechanical vibration, which reduces the probability of mechanical failure of vibration-sensitive components. The smaller rates of gradient changes permit gradient power supplies and amplifiers to operate at reduced voltages. The lower gradient transition rates induce less intense eddy currents in the conductive structures of the scanner magnet, thereby simplifying eddy current compensation. The lower gradient transition rates also reduce the probability of patients experiencing nerve stimulation.

Almost all standard pulse sequences used today employ spin or gradient echoes to generate the magnetic resonance signals acquired by an MRI system. Typically, the production of a spin or gradient echo signal requires magnetic field gradient transitions. The time from the initial excitation of the signal by the pulse sequence to the maximum amplitude of the echo is the echo time (“TE”). The pulse sequence, including the gradient transitions, must be played out in a time comparable to or shorter than the T₂ or T₂* time constants of the material being imaged to elicit the desired contrast information. Therefore, materials or tissues with very short T₂ or T₂* require a pulse sequence with a very short TE if they are to be imaged. However, it is significantly challenging for clinical MRI systems to achieve very short TEs using typical pulse sequences.

A pulse sequence with zero echo time (“ZTE”) provides an advantageous techniques for imaging substances or tissues with short T₂ or T₂* values. Such pulse sequences acquire the magnetic resonance signal immediately following an RF pulse, the free induction decay (“FID”) signal, rather than forming and sampling an echo signal. However, there are problems with using FID signals instead of the echo signal, most notably constraining data acquisition to the FID signal duration, rather than allowing the acquisition to play out over the echo period.

Three general examples of approaches to acquiring signals from tissues with short T₂ or T₂* values include using ultrashort echo time (“UTE”) pulse sequences, ZTE pulse sequences, and the sweep imaging with Fourier transformation (“SWIFT”) pulse sequence. UTE requires gradient switching, and is therefore is a substantially loud measurement method. SWIFT uses very sparely switched gradients, and is, therefore, comparatively quiet. However, SWIFT is difficult to implement on clinical scanners, and it can be problematic to combine SWIFT with commonly used pulse sequence features, such as water or fat signal suppression.

The present invention provides a new ZTE pulse sequence to provide substantially quiet MRI. That is, the present invention recognizes that a particular group of variations on ZTE pulse sequences has proved particularly useful for imaging bone and synthetic biomaterials. The common feature of these ZTE sequences is that they capture the FID following a single intense, hard RF pulse in the presence of a fixed amplitude gradient, thereby mapping out radii in an isotropically sampled spherical volume of k-space (the Fourier space of the image). By eliminating all gradient switching during the acquisition of one k-space radius, it is possible to capture the signals from extremely short T₂ or T₂* tissues, such as bone, with high fidelity. Even with this technique, the first few microseconds of signal following the RF pulse are lost in the receiver recovery time (the time the signal receiver requires to electronically recover from the overload caused by the intense RF excitation pulse and begin to amplify the MR signal). However, it is possible to recover this lost data clustered in a small volume about the k-space origin by acquiring a small number of additional radii under a reduced gradient magnitude. This displaces the central k-space points out to larger times following the RF pulse, beyond the receiver recovery time, where they can be faithfully sampled.

Generally, in accordance with the present invention, a ZTE pulse sequence is modified by removing gradient pulse gaps between successive k-space radii, which makes more effective use of the available gradient duty cycle and reduces total scan duration. Additionally, the present invention recognizes that the ordering of gradient steps can be designed according to a pattern such that successive gradient directions differ by vanishingly small steps, thereby avoiding nearly reversed gradients (which create huge gradient transitions) on alternate scans. The creation of this specially-designed gradient pattern has the additional benefit of preventing the formation of spurious gradient echoes. A pulse sequence in accordance with the present invention may also include RF spoiling (variation of the RF phase from scan to scan) to further limit spurious echo formation. The cumulative effect of these modifications is the elimination of all large scale gradient field transitions, which effectively renders the pulse sequence substantially quiet. Despite the fact that no spin or gradient echoes are formed with this modified pulse sequence, images of clinically acceptable quality are obtained. In addition to being very quiet, this pulse sequence works well for imaging tissues or substances with short T₂ or T₂* because of the ZTE feature.

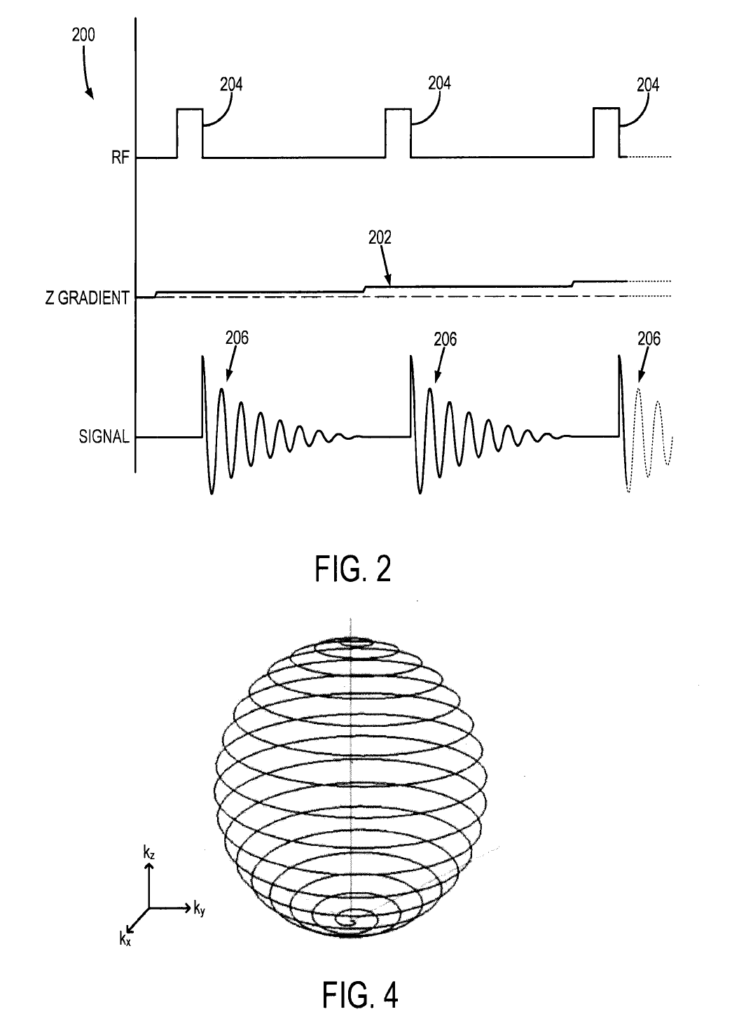

Referring now to FIG. 2, an example of a quiet pulse sequence is illustrated. This pulse sequence eliminates large scale gradient field transitions by closing the gap in the field gradient program during pulse sequence repetitions, and creates a desired pattern by appropriately reordering gradient steps such that the gradient transition from one sequence repetition to the next is controlled, for example, vanishingly small. The pulse sequence 200 includes the continuous generation of a magnetic field gradient 202, which is illustrated as being stepped through a plurality of different values. As noted above, the transitions between subsequent steps of the gradient 202 are made significantly small. For example, a desirable transition size may be, as a non-limiting example, 1/1000 of the maximum amplitude of a vector component of the magnetic field gradient. A desired transition size may serve as a threshold for the designing of a quite pulse sequence. The pulse sequence also includes the application of an RF excitation pulse 204 following the transition from one gradient 202 step to the next. The RF excitation pulse 204 may be, for example, a single, intense, short (“hard”) rectangular RF pulse, but other RF pulse shapes are within the scope of the invention. After the termination of the RF pulse 204, a free induction decay (“FID”) magnetic resonance signal 206 is formed. The acquisition of the magnetic resonance signal 206 may correspond to the acquisition of one radius of data in three-dimensional k-space.

This pulse sequence 200, which controls gradient transitions to be below a desired threshold, yields good quality images and is nearly completely quiet. The pulse sequence includes certain features to further control auditory noise during scanning, specifically the absence of large and rapid magnetic field gradient changes. For example, by designing the pulse sequence 200 to be a ZTE sequence, it may be advantageous for brain and body imaging where susceptibility artifacts cannot be tolerated, or for other imaging applications where the zero echo time feature is advantageous, such as in bone and solid state imaging. The pulse sequence 200 can be used to generate three-dimensional images directly. Radial k-space acquisitions generally are more tolerant of tissue motion, making the pulse sequence 200 when embodied as a radial acquisition further advantageous for abdominal imaging, in which the motion is not periodic as in the heart, and therefore cannot be acquired with a gating procedure.

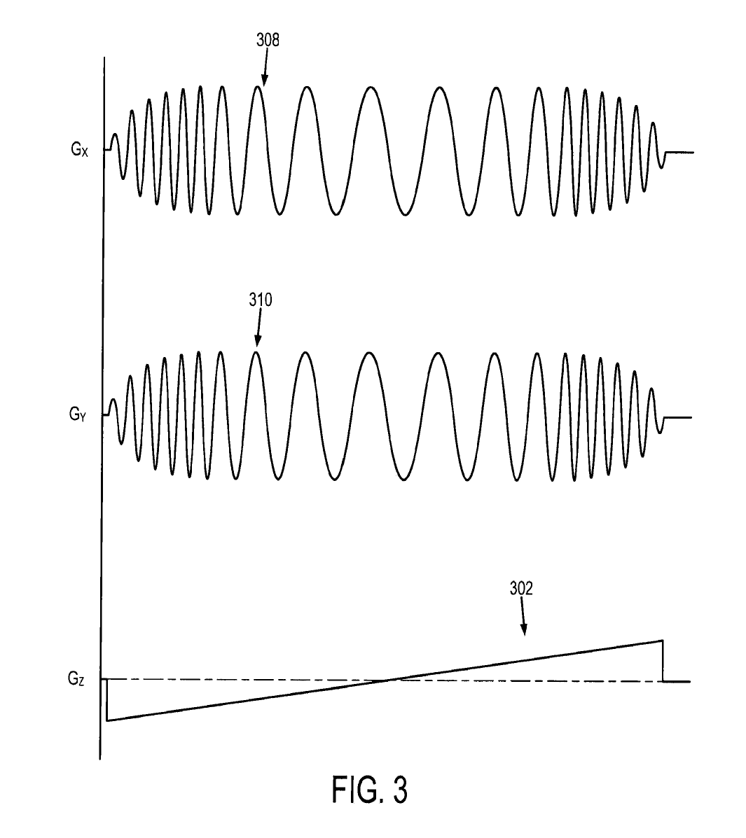

An example of a spatial-encoding gradient pattern (an Archimedian spiral in three dimensions) that may be used in the quiet pulse sequences of the present invention is illustrated in FIG. 3. In this example, the G_{z} gradient component 302 is established in the presence of a Gₓ gradient component 308 and a G_{y} gradient component 310 such that the magnitude of the gradient (the vector sum Gₓ+G_{y}+G_{z} of the three gradient component vectors) is constant during the entire pulse sequence. The G_{z} gradient component 302 is stepped linearly during the entire pulse sequence, while the Gₓ and G_{y} components 308 and 310 are stepped such that the tip of the k-space radius vector sweeps out a three dimensional Archimedean spiral trajectory, such as the one illustrated in FIG. 4, in which the surface of the k-space sphere is sampled at constant density in solid angle. The gradient pulse sequence may also include a slow turn-on and turn-off at the beginning and end of the G_{z} gradient component 302 sequence to eliminate the clicking noise created by the sudden turn-on and turn-off of this component.

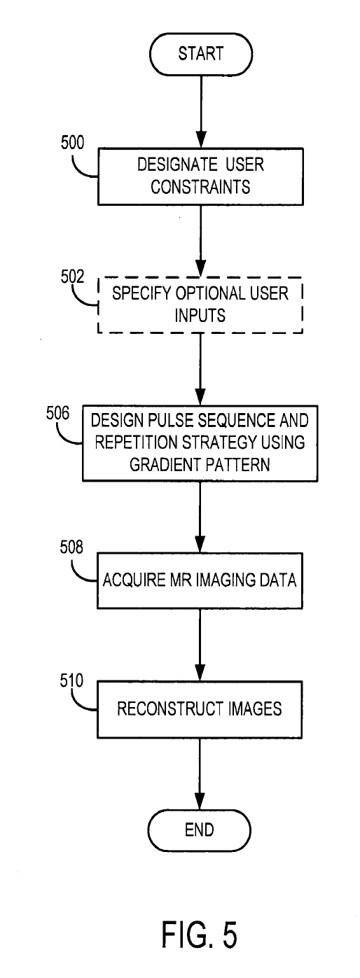

Referring to FIG. 5, a flow chart is provided to illustrate one example of an implementation of the present invention. The process begins at process block 500, with the designation of user constraints for the imaging protocol. For example, the user will specify traditional imaging criteria, parameters, and constraints. In addition, the user may be provided with the option of communicating an amount of auditory noise tolerated during the imaging process or may simply specify the clinical constraints for the imaging process and allow the system to specify default imaging parameters that the user may or may not adjust. For example, there are a variety of parameters that may be varied in the quiet pulse sequences provided in accordance with the present invention. Some may be used to adjust the image contrast. Others may be used to adjust parameters not related to image contrast or the like. Specific examples of adjustable parameters will be described below. Of course, the imaging constraints may be the primary consideration in selecting the features of a to-be prescribed pulse sequence; however, in accordance with the present invention, the user may also provide information about the relative noise tolerance or lack thereof.

For example, at optional process block 502, one or more thresholds may be selected by a user based on a plurality of criteria. For example, a user may specify the age of the patient or other information that may serve as an input to anticipate the nose tolerance of the patient. As described above, the magnetic field gradient may be constrained by at least two criteria; namely, maintaining a continuous gradient and controlling a difference between successive gradient amplitudes. Thus, such optional user inputs may be used to determine a tolerance with respect to such criteria. For example, such optional inputs may be used to determine a tolerance with respect the pulse sequence including gradients that remain non-zero. This may be referred to as a non-zero gradient threshold or tolerance. A second criteria or tolerance may be use to control auditory noise caused by the change in forces generated during transitions between the successive gradient amplitudes or between repetitions of the pulse sequence. Thus, a preliminary pattern for successive gradient directions of a plurality of different gradient amplitudes may be compared to a threshold or tolerance to ensure that successive gradient values differ by less than a value that may be selected, for example, based on these optional user inputs. In this regard, a gradient variance and gradient strength (which, when compared to the tissue spectral resolution, determines the true spatial resolution achieved in the image) is chosen first. If these parameters result in gradient steps that are small enough, then the scan will be quiet. Simply, the smaller the steps, the quieter the scan will be. The tolerance for step size, can be determined based on the optional user inputs or can be set to default or predetermined values by the system.

At process block 506, these thresholds and other user constraints may be used to design a pulse sequence that implements a gradient pattern that accomplishes the desired scanning results while maintaining low acoustic noise. The variability of the pulse sequence design is somewhat limited because the magnetic gradient field is on continuously and cannot change by large steps and, therefore, there are no gradient pulses whose timing and amplitude may be adjusted to manipulate image contrast. However, clinically-acceptable imaging can be readily accomplished and tailored to clinical needs. In the quiet ZTE sequences, T₁ contrast may be established and modified by varying the repetition time (“TR”) and/or the RF flip angle. To establish and modify T₂ contrast between tissues or materials with different values of T₂ or T₂*, the gradient magnitude may be varied. By varying the gradient magnitude, the effective point spread function of the image is also varied, which creates more or less blurring for shorter T₂ or T₂* substances relative to substances with longer T₂ or T₂* for a given image spatial resolution. The RF pulses in the quiet ZTE sequences can be varied, for example by adding additional pulses to generate spin echoes, thereby introducing an echo time that can be varied to adjust contrast based on transverse relaxation times. The RF pulses may also be modified to have various amplitudes and phases to achieve volume selection, B₁ and B₀ inhomogeneity compensation, T₂ or T₂* selectivity, and similar features. All such variations of the RF pulses are within the scope of the invention.

At process block 508, with the pulse sequence and repetition plan designed, MR data acquisition from the subject commences. With the desired MR imaging data acquired, the acquired data can then be reconstructed into images of the subject at process block 510.

Although the above-described quiet pulse sequences have the benefit of being substantially quiet, they are also advantageous for specific imaging applications, such as brain and body imaging where susceptibility artifacts cannot be tolerated, or for other imaging applications where a zero echo time feature is advantageous, such as in bone and solid state imaging. The pulse sequences of the present invention are more tolerant of tissue motion and flow than many popular and loud pulse sequences, making the pulse sequences of the present invention advantageous for abdominal imaging, in which aperiodic motion of the bowel would create significant image artifacts if pulse sequences of the present invention are not used. Also, the pulse sequences of the present invention are advantageous for lung and abdominal imaging because they are generally insensitive to susceptibility differences between gas and the surrounding tissue, which otherwise cause significant signal dephasing.

Reducing the field gradient component transitions to very small values in the present invention to reduce the noise of the scanner also has the very desirable effect of reducing eddy currents in the metal structures of the magnet assembly, the RF coils and in implants in the body of the subject being scanned. Therefore it should be understood that the present invention is also a means to reduce eddy currents during MRI scanning.

The present invention has been described in terms of one or more preferred embodiments, and it should be appreciated that many equivalents, alternatives, variations, and modifications, aside from those expressly stated, are possible and within the scope of the invention.

1. A method for controlling a magnetic resonance imaging (MRI) system to control auditory noise, the steps of the method comprising:
directing an MRI system to perform a pulse sequence that includes:
i) maintaining a magnetic field gradient during each repetition of the pulse sequence;
ii) stepping the magnetic field gradient vector components through a plurality of different gradient amplitudes in a pattern that controls a difference between successive gradient component amplitudes to be less than a predetermined value to control auditory noise caused by forces generated during transitions between the successive gradient amplitudes; and
wherein the pattern is designed to control a transition between successive gradient amplitudes in successive repetitions of the pulse sequence to be less than the predetermined value to control auditory noise caused by forces generated during transitions between the successive gradient amplitudes between the successive repetitions of the pulse sequence.

2. The method as recited in claim 1 in which the pulse sequence further includes applying a radio frequency (RF) pulse after each transition between successive gradient component amplitudes.

3. The method as recited in claim 2 in which the MRI system is further directed to sample a magnetic resonance signal associated with a free induction decay that occurs after each application of the RF pulse.

4. The method as recited in claim 1 in which the pulse sequence further includes applying a radio frequency (RF) pulse that spoils magnetic resonance echo formation.

5. The method as recited in claim 1 in which the pattern is designed such that the predetermined value is less than 1/1000 of a maximum value of any gradient component amplitude in the pulse sequence.

6. The method as recited in claim 1 in which the difference between successive gradient component amplitudes in one repetition of the pulse sequence is zero.

7. A magnetic resonance imaging (MRI) system, comprising:
a magnet system configured to generate a polarizing magnetic field about at least a portion of a subject arranged in the MRI system;
a magnetic gradient system including a plurality of magnetic gradient coils configured to apply at least one magnetic gradient field to the polarizing magnetic field;
a radio frequency (RF) system configured to apply an RF field to the subject and to receive magnetic resonance signals therefrom;
a computer system programmed to:
direct the magnetic gradient system to step the magnetic field gradient through a plurality of gradient component amplitude values in a pattern that controls a difference between successive gradient component amplitudes to be less than a predetermined value to control auditory noise caused by forces generated during transitions between the successive gradient amplitudes;
direct the RF system to coordinate with the magnetic gradient system to acquire MR imaging data from the subject; and
reconstruct an image of the subject from the MR imaging data.

8. The MRI system as recited in claim 7 in which the computer system is further programmed to direct the RF system to apply an RF pulse after each transition between successive gradient component amplitudes.

9. The MRI system as recited in claim 8 in which the computer system is programmed to direct the RF system to receive a magnetic resonance signal associated with a free induction decay that occurs after each applied RF pulse to acquire the MR imaging data.

10. The MRI system as recited in claim 7 in which the computer system is programmed to direct the RF system to apply an RF pulse that spoils magnetic resonance echo formation.

11. The MRI system as recited in claim 5 in which the difference between successive gradient component amplitudes in one repetition of the pulse sequence is zero.

12. A method for magnetic resonance imaging (MRI) with significant noise reduction, the steps of the method comprising:
directing an MRI system to perform a pulse sequence that includes:
i) continuously establishing a magnetic field gradient during each repetition of the pulse sequence;
ii) stepping the continuously established magnetic field gradient through a plurality of different gradient component amplitudes such that a difference between successive gradient component amplitudes is sufficiently small so as to substantially mitigate force changes generated during transitions between the successive gradient amplitudes.

13. The method as recited in claim 12 in which the pulse sequence further includes applying a radio frequency (RF) pulse after each transition between successive gradient amplitudes.

14. The method as recited in claim 13 in which the MRI system is further directed to sample a magnetic resonance signal associated with a free induction decay that occurs after each application of the RF pulse.

15. The method as recited in claim 12 in which the pulse sequence further includes applying a radio frequency (RF) pulse that spoils magnetic resonance echo formation.

16. A magnetic resonance imaging (MRI) system, comprising:
a magnet system configured to generate a polarizing magnetic field about at least a portion of a subject arranged in the MRI system;
a magnetic gradient system including a plurality of magnetic gradient coils configured to apply at least one magnetic gradient field to the polarizing magnetic field;
a radio frequency (RF) system configured to apply an RF field to the subject and to receive magnetic resonance signals therefrom;
a computer system programmed to:
direct the magnetic gradient system to continuously establish a magnetic field gradient;
direct the magnetic gradient system to step the continuously established magnetic field gradient through a plurality of gradient component amplitude values in which a difference between each successive gradient amplitude value is sufficiently small so as to substantially mitigate forces being generated between the magnet system and the magnetic gradient system; and
direct the magnetic gradient system to order the plurality of magnetic gradient amplitude values such that a transition between successive repetitions of a pulse sequence that includes the continuously established magnetic field gradient is sufficiently small so as to substantially mitigate forces being generated between the magnet system and the magnetic gradient system.

17. The MRI system as recited in claim 16 in which the computer system is further programmed to direct the RF system to apply an RF pulse after each transition between successive gradient amplitudes.

18. The MRI as recited in claim 17 in which computer system is programmed to direct the RF system to receive a magnetic resonance signal associated with a free induction decay that occurs after each applied RF pulse.

19. The MRI system as recited in claim 16 in which the computer system is programmed to direct the RF system to apply an RF pulse that spoils magnetic resonance echo formation.

20. The MRI system as recited in claim 16 in which the computer system is further programmed to direct the RF system to coordinate with the magnetic gradient system to acquire MR imaging data from the subject and reconstruct an image of the subject from the MR imaging data.
